(19) United States
(12) Patent Application Publication
(10) Pub. No.: US 2018/0033552 A1
(43) Pub. Date: Feb. 1, 2018

(54) MULTILAYER CERAMIC ELECTRONIC COMPONENT TO BE EMBEDDED IN BOARD AND PRINTED CIRCUIT BOARD HAVING MULTILAYER CERAMIC ELECTRONIC COMPONENT EMBEDDED THEREIN

(71) Applicant: SAMSUNG ELECTRO-MECHANICS CO., LTD., Suwon-si (KR)

(72) Inventors: Byoung Hwa LEE, Suwon-si (KR); Doo Young KIM, Suwon-si (KR); Hai Joon LEE, Suwon-si (KR); Jin Man JUNG, Suwon-si (KR)

(21) Appl. No.: 15/728,183

(22) Filed: Oct. 9, 2017

Related U.S. Application Data
(63) Continuation of application No. 14/083,189, filed on Nov. 18, 2013.

(30) Foreign Application Priority Data
Jul. 22, 2013 (KR) 10-2013-0086324

(51) Int. Cl. H01G 2/06; H01G 4/30; H01G 4/232; H05K 3/00; H05K 1/18; H01G 4/012

(52) U.S. Cl. CPC H01G 2/06; H05K 1/185; H01G 4/012; H01G 4/232; H05K 3/0035; H01G 4/30; Y02P 70/611; H05K 2201/10015; H05K 2201/10636

(57) ABSTRACT

There is provided a multilayer ceramic electronic component to be embedded in a board, including a ceramic body including dielectric layers and having first and second main surfaces facing each other, first and second side surfaces facing each other, and first and second end surfaces facing each other, an active layer including a plurality of first and second internal electrodes alternately exposed through both end surfaces of the ceramic body with the dielectric layers interposed therebetween, to form capacitance therein, upper and lower cover layers formed on upper and lower portions of the active layer, and first and second external electrodes formed on both end surfaces of the ceramic body, wherein when a thickness of the upper or lower cover layer is defined as tc, 4 μm≦tc≦20 μm may be satisfied.

### CROSS-REFERENCE TO RELATED APPLICATIONS

This application is a Continuation application of U.S. patent application Ser. No. 14/083,189, filed on Nov. 18, 2013, which in turn claims the priority of Korean Patent Application No. 10-2013-0086324 filed on Jul. 22, 2013, in the Korean Intellectual Property Office, the disclosures of which applications are incorporated herein by reference.

### BACKGROUND OF THE INVENTION

### Field of the Invention

The present invention relates to a multilayer ceramic electronic component to be embedded in a board and a printed circuit board having a multilayer ceramic electronic component embedded therein.

### Description of the Related Art

As electronic circuits have become highly densified and highly integrated, a mounting space for passive elements mounted on a printed circuit board (PCB) has become insufficient, and in order to solve this problem, ongoing efforts have been made to implement components able to be installed within a board, i.e., embedded devices. In particular, various methods have been proposed for installing a multilayer ceramic electronic component used as a capacitive component within a board.

In one of a variety of methods of installing a multilayer ceramic electronic component within a board, the same dielectric material used for a multilayer ceramic electronic component is used as a material for a board and a copper wiring, or the like, is used as an electrode. Other methods for implementing a multilayer ceramic electronic component to be embedded in a board include a method of forming the multilayer ceramic electronic component to be embedded in the board by forming a polymer sheet having high-k dielectrics and a dielectric thin film within the board, a method of installing a multilayer ceramic electronic component within a board, and the like.

In general, a multilayer ceramic electronic component includes a plurality of dielectric layers formed of a ceramic material, and internal electrodes interposed between the dielectric layers. By disposing such a multilayer ceramic electronic component within a board, a multilayer ceramic electronic component to be embedded in a board having high capacitance may be implemented.

In order to manufacture a printed circuit board (PCB) including a multilayer ceramic electronic component embedded therein, a multilayer ceramic electronic component may be inserted into a core board, and via holes are required to be formed in an upper laminated plate and a lower laminated plate by using a laser in order to connect board wirings and external electrodes of the multilayer ceramic electronic component. Laser beam machining, however, considerably increases manufacturing costs of a PCB.

Meanwhile, since the multilayer ceramic electronic component needs to be embedded in the core portion of the board, a nickel/tin (Ni/Sn) plating layer does not need to be formed on the external electrode, unlike in the case of a general multilayer ceramic electronic component mounted on a surface of a board.

That is, since the external electrode of the multilayer ceramic electronic component to be the embedded in the board is electrically connected to a circuit in the board through a via formed of copper (Cu), instead of through a nickel/tin (Si/Sn) layer, a copper (Cu) layer needs to be formed on the external electrode.

Generally, since even the external electrode is formed of copper (Cu) as a main component but also includes glass, the glass component absorbs the laser during laser beam machining for forming the via in the board, and thus, it may be difficult to adjust a depth of the via.

For this reason, such a copper (Cu) plating layer has been separately formed on the external electrode of the multilayer ceramic electronic component to be embedded in the board.

Meanwhile, in the case of a multilayer ceramic electronic component to be embedded in a board, the multilayer ceramic electronic component may be embedded in a printed circuit board (PCB) used for a memory card, a PC main board, and various RF modules, whereby a product size may be significantly reduced, as compared to the case of using a multilayer ceramic electronic component mounted on a board.

Also, since the multilayer ceramic electronic component may be disposed to be fairly close to an input terminal of an active element such as a micro-processor unit (MPU), interconnect inductance due to a wire length may be reduced.

However, such an effect of reducing inductance in a multilayer ceramic electronic component to be embedded in a board merely results from a reduction in interconnect inductance obtained by a disposition method, an embedding scheme, and it has not yet affected an improvement in equivalent series inductance (ESL) characteristics of a multilayer ceramic electronic component to be embedded in a board.

In general, in a multilayer ceramic electronic component to be embedded in a board, in order to lower equivalent series inductance (ESL), a current path within the multilayer ceramic electronic component is required to be reduced.

However, since a separate copper (Cu) plating layer is formed on an external electrode of a multilayer ceramic electronic component to be embedded in a board, the permeation of a plating solution into the external electrode may be caused, making it difficult to shorten an internal current path.

### RELATED ART DOCUMENT

(Patent Document 1) Korean Patent Laid-Open Publication No. 2006-0047733

### SUMMARY OF THE INVENTION

An aspect of the present invention provides a multilayer ceramic electronic component to be embedded in a board and a printed circuit board having a multilayer ceramic electronic component embedded therein.

According to an aspect of the present invention, there is provided a multilayer ceramic electronic component to be embedded in a board, including: a ceramic body including dielectric layers and having first and second main surfaces facing each other, first and second side surfaces facing each other, and first and second end surfaces facing each other; an active layer including a plurality of first and second internal electrodes alternately exposed through both end surfaces of the ceramic body with the dielectric layers interposed therebetween, to form capacitance therein; upper and lower cover layers formed on upper and lower portions of the active layer; and first and second external electrodes formed on both end surfaces of the ceramic body, wherein the first external electrode includes a first base electrode and a first terminal electrode formed on the first base electrode, the second external electrode includes a second base electrode and a second terminal electrode formed on the second base electrode, and when a thickness of the upper or lower cover layer is defined as tc, 4 μm≦tc≦20 μm may be satisfied.

When a thickness of a region of the first or second base electrode connected to the uppermost internal electrode among the first and second internal electrodes is defined as ta, 10 μm≦ta≦50 μm may be satisfied.

The first and second terminal electrodes may be formed of copper (Cu).

When a thickness of the first and second terminal electrodes is defined as tp, tp≧5 μm may be satisfied.

When surface roughness of the first and second terminal electrodes is defined as Ra and a thickness of the first and second terminal electrodes is defined as tp, 200 nm≦Ra≦tp may be satisfied.

The first and second terminal electrodes may be formed through plating.

When a thickness of the ceramic body is defined as ts, ts≦250 μm may be satisfied.

According to another aspect of the present invention, there is provided a printed circuit board having a multilayer ceramic electronic component embedded therein, the printed circuit board including: an insulating substrate; and the multilayer ceramic electronic component including, a ceramic body including dielectric layers and having first and second main surfaces facing each other, first and second side surfaces facing each other, and first and second end surfaces facing each other; an active layer including a plurality of first and second internal electrodes alternately exposed through both end surfaces of the ceramic body with the dielectric layers interposed therebetween, to form capacitance therein; upper and lower cover layers formed on upper and lower portions of the active layer; and first and second external electrodes formed on both end surfaces of the ceramic body, wherein the first external electrode includes a first base electrode and a first terminal electrode formed on the first base electrode, the second external electrode includes a second base electrode and a second terminal electrode formed on the second base electrode, and when a thickness of the upper or lower cover layer is defined as tc, 4 μm≦tc≦20 μm may be satisfied.

When a thickness of a region of the first or second base electrode connected to the uppermost internal electrode among the first and second internal electrodes is defined as ta, 10 μm≦ta≦50 μm may be satisfied.

The first and second terminal electrodes may be formed of copper (Cu).

When a thickness of the first and second terminal electrodes is defined as tp, tp≧5 μm may be satisfied.

When surface roughness of the first and second terminal electrodes is defined as Ra and a thickness of the first and second terminal electrodes is defined as tp, 200 nm≦Ra≦tp may be satisfied.

The first and second terminal electrodes may be formed through plating.

When a thickness of the ceramic body is defined as ts, ts≦250 μm may be satisfied.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of a multilayer ceramic electronic component to be embedded in a board according to an embodiment of the present invention;

FIG. 2 is a cross-sectional view taken along line X-X′ of FIG. 1;

FIG. 3 is an enlarged view of region A in FIG. 2; and

FIG. 4 is a cross-sectional view of a printed circuit board having a multilayer ceramic electronic component embedded therein according to an embodiment of the present invention.

### DETAILED DESCRIPTION OF THE PREFERRED EMBODIMENT

Hereinafter, embodiments of the present invention will be described in detail with reference to the accompanying drawings.

The invention may, however, be embodied in many different forms and should not be construed as being limited to the embodiments set forth herein.

Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

Multilayer Ceramic Electronic Component to be Embedded in Board

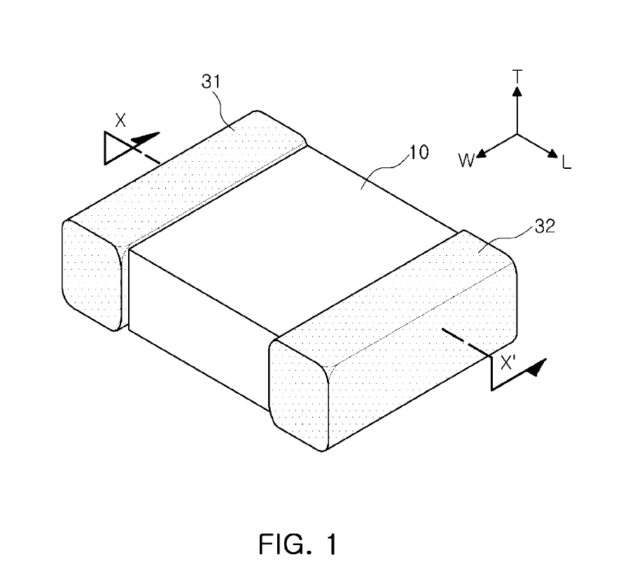

FIG. 1 is a perspective view of a multilayer ceramic electronic component to be embedded in a board according to an embodiment of the present invention.

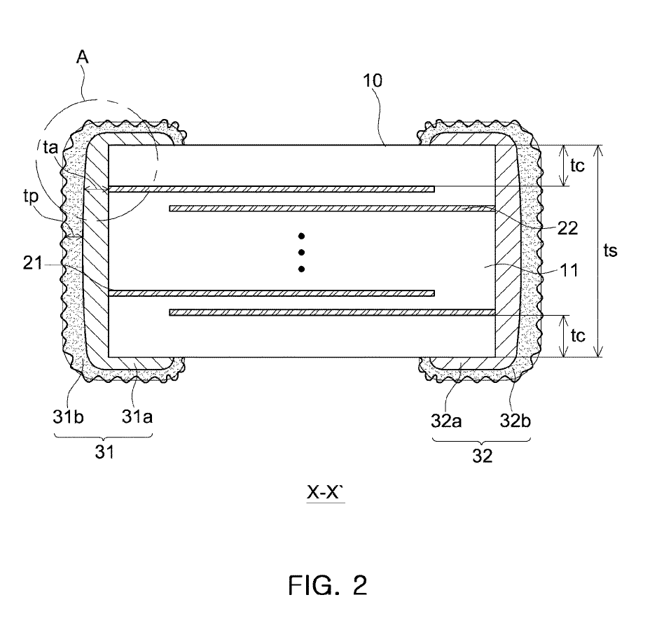

FIG. 2 is a cross-sectional view taken along line X-X′ of FIG. 1.

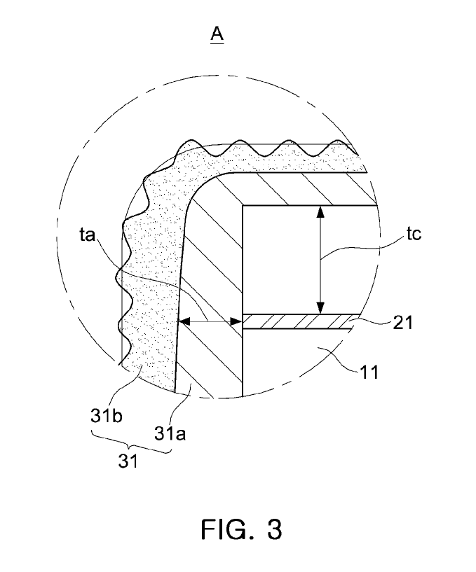

FIG. 3 is an enlarged view of region A in FIG. 2.

Referring to FIGS. 1 through 3, a multilayer ceramic electronic component to be embedded in a board according to an embodiment of the present invention may include a ceramic body 10 including dielectric layers 11 and having first and second main surfaces facing each other, first and second side surfaces facing each other, and first and second end surfaces facing each other; an active layer including a plurality of first and second internal electrodes 21 and 22 alternately exposed through both end surfaces of the ceramic body 10 with the dielectric layers 11 interposed therebetween, to form capacitance therein; upper and lower cover layers formed on upper and lower portions of the active layer; and first and second external electrodes 31 and 32 formed on both end surfaces of the ceramic body 10, wherein the first external electrode 31 includes a first base electrode 31a and a first terminal electrode 31b formed on the first base electrode 31a, the second external electrode 32 includes a second base electrode 32a and a second terminal electrode 32b formed on the second base electrode 32a, and when a thickness of the upper or lower cover layer is defined as tc, 4 μm≦tc≦20 μm may be satisfied.

Hereinafter, the multilayer ceramic electronic component according to the embodiment of the present invention will be described by taking a multilayer ceramic capacitor by way of example, but the invention is not limited thereto.

In the multilayer ceramic capacitor according to the embodiment of the present invention, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1. Here, the ‘thickness direction’ is the same as a direction in which dielectric layers are stacked, that is, a ‘stacking direction’.

According to the embodiment of the invention, a shape of the ceramic body 10 is not particularly limited, but may be hexahedral as illustrated.

According to the embodiment of the present invention, the ceramic body 10 may have the first and second main surfaces facing each other, the first and second side surfaces facing each other, and the first and second end surfaces facing each other. Here, the first and second main surfaces refer to upper and lower surfaces of the ceramic body 10.

A thickness ts of the ceramic body 10 may be equal to or less than 250 μm.

Since the ceramic body 10 is fabricated to have the thickness ts equal to or less than 250 μm, the MLCC may be suitable to be embedded in a board.

The thickness is of the ceramic body 10 may be a distance between the first main surface and the second main surface.

According to the embodiment of the invention, a raw material forming the dielectric layers 11 is not particularly limited as long as sufficient capacitance may be obtained thereby, but may be, for example, a barium titanate (BaTiO₃) powder.

As a material forming the dielectric layer 11, various ceramic additives, organic solvents, plasticizers, binders, dispersing agents, and the like, may be added to powder such as barium titanate (BaTiO₃) powder and the like.

An average particle diameter of the ceramic powder used to form the dielectric layer 11 is not particularly limited, but may be adjusted to satisfy desired dielectric properties. For example, an average particle diameter of the ceramic powder may be adjusted to be equal to or less than 400 nm.

The ceramic body 10 may include the active layer contributing to the formation of capacitance of the capacitor and the upper and lower cover layers formed on the upper and lower portions of the active layer, respectively, as upper and lower margin portions.

The active layer may be formed by repeatedly stacking the plurality of first and second internal electrodes 21 and 22 with the dielectric layers 11 interposed therebetween.

The upper and lower cover layers may be formed of the same material and have the same configuration as those of the dielectric layers 11, except that the upper and lower cover layers have no internal electrodes.

The upper and lower cover layers may be respectively formed by stacking a single dielectric layer or two or more dielectric layers on upper and lower surfaces of the active layer in a vertical direction. Basically, the upper and lower cover layers serve to prevent damage to the internal electrodes due to physical or chemical stress.

In particular, in case of a multilayer ceramic electronic component to be embedded in a board, since a copper (Cu) plating layer is additionally formed on external electrodes, internal electrodes may be damaged due to the permeation of a plating solution.

Thus, in case of a general multilayer ceramic electronic component to be embedded in a board, upper and lower cover layers are formed to be relatively thick to prevent damage to internal electrodes due to the permeation of a plating solution.

However, when upper and lower cover layers are formed to be relatively thick, a current path within the multilayer ceramic electronic component to be embedded in a board may be lengthened, making it difficult to reduce equivalent series inductance (ESL).

According to an embodiment of the present invention, when a thickness of the upper or lower cover layer is defined as tc, 4 μm≦tc≦20 μm may be satisfied.

Since the thickness tc of the upper and lower cover layers may be adjusted to satisfy 4 μm≦tc≦20 μm, a current path within the multilayer ceramic electronic component to be embedded in a board may be shortened, reducing equivalent series inductance (ESL).

If the thickness tc of the upper or lower cover layer is less than 4 μm, the thickness of the cover layer may be excessively small, causing a degradation in reliability according to moisture-resistant characteristics.

Meanwhile, if the thickness tc of the upper or lower cover layer exceeds 20 μm, a current path within the multilayer ceramic electronic component to be embedded in a board may be lengthened, and thus, equivalent series inductance (ESL) may not be reduced and capacitance may not be easily implemented.

Meanwhile, the first and second internal electrodes 21 and 22 are pairs of electrodes having different polarities. The first and second internal electrodes 21 and 22 may be formed by printing a conductive paste including a conductive metal on the dielectric layer 11 at a predetermined thickness.

Also, the first and second internal electrodes 21 and 22 may be alternately exposed through both end surfaces of the ceramic body in the stacking direction of the dielectric layers 11 and may be electrically insulated from each other by the dielectric layers 11 disposed therebetween.

Namely, the first and second internal electrodes 21 and 22 may be electrically connected to the first and second external electrodes 31 and 32, respectively, through portions thereof alternately exposed to both end surfaces of the ceramic body 10.

Thus, when a voltage is applied to the first and second external electrodes 31 and 32, charges are accumulated between the first and second internal electrodes 21 and 22 opposed to each other, and in this case, capacitance of the MLCC is proportional to an area of a region in which the first and second internal electrodes 21 and 22 overlap each other.

Also, a conductive metal included in the conductive paste used to form the first and second internal electrodes 21 and 22 may be nickel (Ni), copper (Cu), palladium (Pd), or an alloy thereof, but the present invention is not limited thereto.

Also, as a printing method of the conductive paste, a screen printing method, a gravure printing method, or the like, may be used, but the present invention is not limited thereto.

According to an embodiment of the present invention, the first and second external electrodes 31 and 32 may be formed on both end surfaces of the ceramic body 10.

The first external electrode 31 may include the first base electrode 31a electrically connected to the first internal electrode 21 and the first terminal electrode 31b formed on the base electrode 31a.

Also, the second external electrode 32 may include the second base electrode 32a electrically connected to the second internal electrode 22 and the second terminal electrode 32b formed on the base electrode 32a.

Hereinafter, structures of the first and second external electrodes 31 and 32 will be described in detail.

The first and second base electrodes 31a and 32a may include a first conductive metal and glass.

In order to form capacitance, the first and second external electrodes 31 and 32 may be formed on both end surfaces of the ceramic body 10 and the first and second base electrodes 31a and 32a of the first and second external electrodes 31 and 32 may be electrically connected to the first and second internal electrodes 21 and 22.

The first and second base electrodes 31a and 32a may be formed of the same conductive material as that of the first and second internal electrodes 21 and 22, but the present invention is not limited thereto and the first and second base electrodes 31a and 32a may be formed of at least one first conductive metal selected from the group consisting of copper (Cu), silver (Ag), nickel (Ni), and an alloy thereof, for example.

The first and second base electrodes 31a and 32a may be formed by applying a conductive paste prepared by adding a glass frit to the first metal powder and then performing firing thereon.

According to an embodiment of the present invention, the first and second external electrodes 31 and 32 may include the first and second terminal electrodes 31b and 32b formed on the first and second base electrodes 31a and 32a.

The first and second terminal electrodes 31b and 32b may be formed of a second conductive metal.

The second conductive metal is not particularly limited. For example, it may be copper (Cu).

In general, a multilayer ceramic capacitor is mounted on a printed circuit bard, and a nickel/tin plating layer is usually formed on an external electrode.

However, the multilayer ceramic capacitor according to the embodiment of the invention is not mounted on the printed circuit board, but is embedded in the board, and thus, the first and second external electrodes 31 and 32 of the multilayer ceramic capacitor are electrically connected to circuits of the board through vias formed of a copper (Cu) material.

Therefore, according to the embodiment of the invention, the first and second terminal electrodes 31b and 32b may be formed of copper (Cu) having good electrical connectivity with respect to the copper (Cu) material forming the vias in the board.

Meanwhile, since the first and second base electrodes 31a and 32a are formed of copper (Cu) as a main component but also include glass, the glass component absorbs laser during laser processing for forming the vias in the board, and thus, it may be difficult to adjust depths of the vias.

For this reason, the first and second terminal electrodes 31b and 32b of the multilayer ceramic electronic component to be embedded in a board may be formed of copper (Cu).

A method for forming the first and second terminal electrodes 31b and 32b is not particularly limited. For example, the first and second terminal electrodes 31b and 32b may be formed through plating.

Thus, after a firing operation, the first and second terminal electrodes 31b and 32b may be formed of only copper (Cu) without a glass frit, difficulties in adjusting the depths of the vias due to the glass component absorbing the laser during laser processing for forming the vias in the board may be avoided.

Meanwhile, according to an embodiment of the present invention, when a thickness of a region of the first or second base electrode 31a or 32a connected to the uppermost internal electrode among the first and second internal electrodes 21 and 22 is defined as ta, 10 μm≦ta≦50 μm may be satisfied.

As described above, in order to reduce equivalent series inductance (ESL) by shortening a current path within the multilayer ceramic electronic component to be embedded in a board, the thickness tc of the upper or lower cover layer may be adjusted to satisfy 4 μm≦tc≦20 μm. In this case, however, a plating solution may permeate into the external electrodes.

Namely, as the thickness of the upper or lower cover layer is reduced, the thickness of a region of the first or second base electrode 31a or 32a connected to the uppermost internal electrode among the first and second internal electrodes 21 and 22 is generally small, such that the permeation of a plating solution may be easily generated.

However, according to the embodiment of the present invention, when a thickness of a region of the first or second base electrode 31a or 32a connected to the uppermost internal electrode among the first and second internal electrodes 21 and 22 is defined as ta, the thickness ta is adjusted to satisfy 10 μm≦ta≦50 μm, thereby preventing the permeation of a plating solution.

Namely, equivalent series inductance (ESL) may be reduced by reducing the thickness tc of the upper or lower cover layer, and at the same time, the first or second base electrode 31a or 32a may be adjusted to prevent the permeation of a plating solution, whereby a multilayer ceramic electronic component to be embedded in a board, having excellent reliability may be implemented.

When the thickness ta of the region of the first or second base electrode 31a or 32a connected to the uppermost internal electrode among the first and second internal electrodes 21 and 22 is less than 10 μm, the permeation of a plating solution may occur to degrade reliability.

When the thickness ta of the region of the first or second base electrode 31a or 32a connected to the uppermost internal electrode among the first and second internal electrodes 21 and 22 exceeds 50 μm, a space for forming capacitance may be reduced, such that an electronic component having high capacitance may not be implemented.

Also, if the thickness of the dielectric layer is reduced in order to implement a high capacitance electronic component, reliability may be degraded.

Meanwhile, when a thickness of the first and second terminal electrodes 31b and 32b is defined as tp, tp≧5 μm may be satisfied.

The thickness tp of the first and second terminal electrodes 31b and 32b may satisfy tp≧5 μm, but the present invention is not limited thereto and the thickness tp of the first and second terminal electrodes 31b and 32b may be less than 15 μm.

In this manner, the thickness tp of the first and second terminal electrodes 31b and 32b may be adjusted to satisfy tp≧5 μm while being less than 15 μm, excellent via process may be performed in a board and an MLCC having excellent reliability may be implemented.

When the thickness tp of the first and second terminal electrodes 31b and 32b is less than 5 μm, a problem that a conductive via hole is connected to the ceramic body 10 at the time of processing the conductive via hole when a multilayer ceramic electronic component is embedded in a PCB as described hereinafter may be generated.

When the thickness tp of the first and second terminal electrodes 31b and 32b exceeds 15 μm, cracks may be generated in the ceramic body 10 due to stress of the first and second terminal electrodes 31b and 32b.

Meanwhile, referring to FIGS. 2 and 3, in the multilayer ceramic electronic component according to the embodiment of the present invention, when surface roughness of the first and second terminal electrodes 31b and 32b is defined as Ra and the thickness of the first and second terminal electrodes 31b and 32b is defined as tp, 200 nm≦Ra≦tp may be satisfied.

Since the surface roughness Ra of the first and second terminal electrodes 31b and 32b is adjusted to satisfy 200 nm≦Ra≦tp, delamination between the multilayer ceramic electronic component and the board may be improved and a generation of cracks may be prevented.

Surface roughness refers to a degree of fine depressions and protrusions formed on a metal surface when the metal surface is processed.

Surface roughness is generated due to a tool used for processing, whether or not a processing method is appropriate, grooves formed as a surface is scratched, rust, or the like. In determining a degree of roughness, a surface is cut in a direction perpendicular thereto and a cross-section thereof having a certain curvature is checked. A height from the lowest point to the highest point of the curved line is taken and determined as an average central line roughness denoted by Ra.

In the present embodiment, average central line roughness of the first and second terminal electrodes 31b and 32b is defined as Ra.

In detail, in order to calculate the average central line roughness Ra of the first and second terminal electrodes 31b and 32b, a virtual central line may be drawn with respect to roughness formed on one surfaces of the first and second terminal electrodes 31b and 32b.

Next, respective distances (e.g., r₁, r₂, r₃ . . . r₁₃) based on the virtual central line of roughness are measured and average values of the respective distances are calculated to be obtained as the average central line roughness Ra of the first and second terminal electrodes 31b and 32b, as in the following Formula.

$${R}_{a} = \frac{\vert {r}_{1} \vert + \vert {r}_{2} \vert + \vert {r}_{3} \vert + … \vert {r}_{n} \vert}{n}$$

The average central line roughness Ra of the first and second terminal electrodes 31b and 32b may be adjusted to be within the range of 200 nm≦Ra≦tp, thereby implementing a multilayer ceramic electronic component having excellent withstand voltage characteristics and high reliability with enhanced adhesive strength with respect to a board.

If the surface roughness of the first and second terminal electrodes 31b and 32b is less than 200 nm, a delamination phenomenon may occur between the multilayer ceramic electronic component and the board.

Meanwhile, if the surface roughness of the first and second terminal electrodes 31b and 32b exceeds the thickness tp of the first and second terminal electrodes 31b and 32b, cracks may be generated.

Hereinafter, a method of manufacturing a multilayer ceramic electronic component to be embedded in a board according to an embodiment of the present invention will be described, but the present invention is not limited thereto.

In the method of manufacturing a multilayer ceramic electronic component to be embedded in a board according to an embodiment of the present invention, a plurality of ceramic green sheets may first be prepared by applying slurry including a barium titanate (BaTiO₃) powder and the like to carrier films and drying the same, thereby forming dielectric layers.

The slurry may be prepared by mixing a ceramic powder, a binder, and a solvent, and the slurry may be used to form the ceramic green sheet having a thickness of several μm by a doctor blade method.

Next, a conductive paste for internal electrodes may be prepared to include 40 to 50 parts by weight of a nickel powder having a nickel particle average size of 0.1 to 0.2 μm.

The conductive paste for internal electrodes may be applied to the green sheets by a screen printing method to thereby form internal electrodes, and then the green sheets having the internal electrodes formed thereon may be stacked in an amount of 400 to 500 layers, whereby the ceramic body 10 may be manufactured.

In the MLCC according to the embodiment of the present invention, the first and second internal electrodes 21 and 22 may be formed to be exposed through both end surfaces of the ceramic body 10, respectively.

Thereafter, a first base electrode and a second base electrode including a first conductive metal and glass may be formed on end surfaces of the ceramic body 10.

The first conductive metal may be at least one selected from the group consisting of, for example, copper (Cu), silver (Ag), nickel (Ni), and an alloy thereof, but the first conductive metal is not particularly limited.

The glass is not particularly limited, but a material having the same composition as that of glass used to manufacture external electrodes of a general multilayer ceramic capacitor may be used.

The first and second base electrodes may be formed on end surfaces of the ceramic body to be electrically connected to the first and second internal electrodes, respectively.

Thereafter, a plating layer formed of a second conductive metal may be formed on the first base electrode and the second base electrode.

The second conductive metal may be, for example, copper (Cu), but it is not particularly limited.

The plating layer may be formed as first and second terminal electrodes.

Other features of the method according to the embodiment are the same as those described above with respect to the above embodiments of the multilayer ceramic electronic component embedded in a circuit and therefore, will not be repeated.

Hereinafter, the present invention will be described in more detail through Examples, but the present invention is not limited thereto.

### INVENTIVE EXAMPLE 1

Moisture resistance load reliability and equivalent series inductance (ESL) according to a thickness of the upper or lower cover layer and a thickness of the first and second base electrodes of the multilayer ceramic electronic component to be embedded in a board according to the embodiment of the present invention were tested.

In order to determine whether or not via processing is defective according to the thickness of the first and second terminal electrodes 31b and 32b, and the occurrence frequency of delamination between bonding surfaces according to surface roughness of the first and second terminal electrodes 31b and 32b, boards having multilayer ceramic electronic components embedded therein were left for 30 minutes under general conditions of chip components for mobile phone motherboards, i.e., a temperature of 85° C. and relative humidity of 85%, and thereafter, the they were tested for inspection.

Table 1 shows moisture resistance reliability and equivalent series inductance (ESL) according to the thickness of the upper or lower cover layer and the thickness of the first and second base electrodes.

TABLE 1

| | Thickness of | Determination | |
|---|---|---|---|
| Thickness of | base | on moisture | |
| cover layer | electrode | resistance | |
| (tc) [um] | (ta) [um] | reliability | ESL [pH] |
| 2 | 7 | X | 138 pH |
| 4 | 7 | X | 143 pH |
| 10 | 7 | X | 151 pH |
| 15 | 7 | X | 159 pH |
| 20 | 7 | X | 167 pH |
| 25 | 7 | X | 189 pH |
| 30 | 7 | X | 197 pH |
| 35 | 7 | X | 205 pH |
| 2 | 10 | X | 138 pH |
| 4 | 10 | ◯ | 143 pH |
| 10 | 10 | ⊚ | 151 pH |
| 15 | 10 | ⊚ | 159 pH |
| 20 | 10 | ⊚ | 167 pH |
| 25 | 10 | ⊚ | 189 pH |
| 30 | 10 | ⊚ | 197 pH |
| 35 | 10 | ⊚ | 205 pH |
| 2 | 15 | X | 138 pH |
| 4 | 15 | ◯ | 143 pH |
| 10 | 15 | ⊚ | 151 pH |
| 15 | 15 | ⊚ | 159 pH |
| 20 | 15 | ⊚ | 167 pH |
| 25 | 15 | ⊚ | 189 pH |
| 30 | 15 | ⊚ | 197 pH |
| 35 | 15 | ⊚ | 205 pH |

X: greater than 50% of defect rate
Δ: 10%~50% of defect rate
◯: 0.01%~10% of defect rate
⊚: less than 0.01% of defect rate

Referring to Table 1, it may be seen that, when the thickness tc of the upper or lower cover layer satisfied 4 μm≦tc≦20 μm, excellent moisture resistance reliability was obtained and equivalent series inductance (ESL) was reduced.

Also, it may be seen that, when the thickness ta of the region of the first or second base electrode connected to the uppermost internal electrode among the first and second internal electrodes was equal to or more than 10 μm, moisture resistance reliability was excellent.

Meanwhile, it may be seen that, when the thickness tc of the upper or lower cover layer was less than 4 μm or when the thickness ta of the region of the first or second base electrode was less than 10 μm, the moisture resistance reliability was degraded.

Meanwhile, it may be seen that when the thickness tc of the upper or lower cover layer exceeded 20 μm, the effect of reducing equivalent series inductance (ESL) was not obtained.

Table 2 below shows whether or not via processing is defective according to the thickness of the first and second terminal electrodes 31b and 32b.

TABLE 2

| Thickness of first and | |
|---|---|
| second terminal electrodes | |
| (μm) | Determination |
| Less than 1 | X |
| 1~2 | X |
| 2~3 | X |
| 3~4 | Δ |
| 4~5 | ◯ |
| 5~6 | ⊚ |
| Greater than 6 | ⊚ |

X: greater than 50% of defect rate
Δ: 10%~50% of defect rate
◯: 0.01%~10% of defect rate
⊚: less than 0.01% of defect rate

Referring to Table 2, it may be seen that, in the case of MLCCs in which the thickness of the first and second terminal electrodes 31b and 32b was equal to or greater than 5 μm, the vias were excellently processed in the board, and thus, the MLCC having excellent reliability was implemented.

Meanwhile, it may be seen that, in case of MLCCs in which the thickness of the first and second terminal electrodes 31b and 32b was less than 5 μm, the vias were processed to be defective.

Table 3 below shows the occurrence frequency of delamination between bonding surfaces according to surface roughness of the first and second terminal electrodes 31b and 32b.

TABLE 3

| Surface roughness of first | |
|---|---|
| and second terminal | |
| electrodes (nm) | Determination |
| Less than 50 | X |
| 50~100 | X |
| 100~150 | Δ |
| 150~200 | ◯ |
| 200~250 | ⊚ |
| Greater than 250 | ⊚ |

X: greater than 50% of defect rate
Δ: 10%~50% of defect rate
◯: 0.01%~10% of defect rate
⊚: less than 0.01% of defect rate

Referring to Table 3, it may be seen that, in case of MLCCs in which surface roughness of the first and second terminal electrodes 31b and 32b was equal to or greater than 200 nm, the occurrence frequency of delamination between bonding surfaces was low, implementing MLCCs having excellent reliability.

Meanwhile, it may be seen that, in the case of MLCCs in which surface roughness of the first and second terminal electrodes 31b and 32b was less than 200 nm, the occurrence frequency of delamination between bonding surfaces was high, degrading reliability.

PCB Having Multilayer Ceramic Electronic Component Embedded Therein

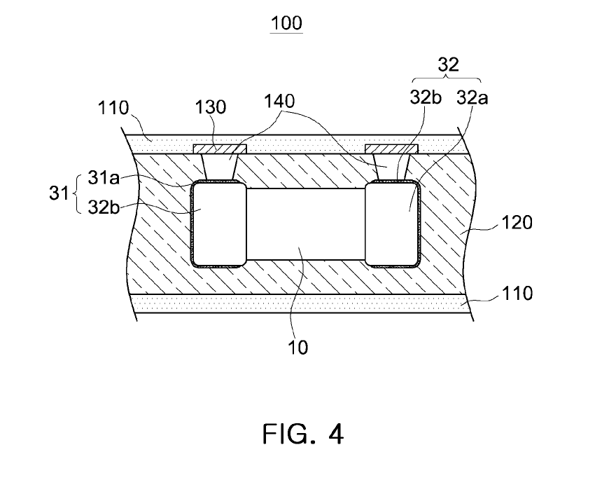

FIG. 4 is a cross-sectional view of a printed circuit board having a multilayer ceramic electronic component embedded therein according to an embodiment of the present invention.

Referring to FIG. 4, a printed circuit board (PCB) 100 having a multilayer ceramic electronic component embedded therein according to an embodiment of the present invention may include: an insulating substrate 110; and the multilayer ceramic electronic component to be embedded in a board including: the ceramic body 10 including dielectric layers 11 and having first and second main surfaces facing each other, first and second side surfaces facing each other, and first and second end surfaces facing each other; the active layer including a plurality of first and second internal electrodes 21 and 22 alternately exposed through both end surfaces of the ceramic body 10 with the dielectric layers 11 interposed therebetween, to form capacitance therein; the upper and lower cover layers formed on upper and lower portions of the active layer; and the first and second external electrodes 31 and 32 formed on both end surfaces of the ceramic body 10, wherein the first external electrode 31 includes a first base electrode 31a and a first terminal electrode 31b formed on the first base electrode 31a, the second external electrode 32 includes a second base electrode 32a and a second terminal electrode 32b formed on the second base electrode 32a, and when a thickness of the upper or lower cover layer is defined as tc, 4 μm≦tc≦20 μm may be satisfied.

The insulating substrate 110 may include an insulating layer 120, and as needed, may include conductive patterns 130 and conductive via holes 140 configuring various types of interlayer circuits as illustrated in FIG. 4. The insulating substrate 110 may be the printed circuit board 100 in which the multilayer ceramic electronic component is provided therein.

The multilayer ceramic electronic component is inserted into the printed circuit board 100, and then may suffer from several harsh conditions during post-processing, such as heat treatment of the printed circuit board 100 and the like.

In particular, the contraction and expansion of the printed circuit board 100 during the heat treatment process directly affect to the multilayer ceramic electronic component inserted into the printed circuit board 100, such that stress may be applied to a bonding surface between the multilayer ceramic electronic component and the printed circuit board 100.

When the stress applied to the bonding surface between the multilayer ceramic electronic component and the printed circuit board 100 is higher than bonding strength, delamination caused by the separation of the bonding surface may occur.

The bonding strength between the multilayer ceramic electronic component and the printed circuit board 100 is in proportion to electrochemical adhesion between the multilayer ceramic electronic component and the printed circuit board 100 and an effective surface area of the bonding surface between the multilayer ceramic electronic component and the printed circuit board 100. In order to improve the effective surface area of the bonding surface, surface roughness of the multilayer ceramic electronic component may be controlled so that the delamination between the multilayer ceramic electronic component and the printed circuit board 100 may be prevented.

Also, the occurrence frequency of delamination between the bonding surfaces between the multilayer ceramic electronic component and the printed circuit board 100 according to surface roughness of the multilayer ceramic electronic component embedded in the PCB 100 may be checked.

Also, in the multilayer ceramic electronic component to be embedded in a board, the thickness tc of the upper or lower cover layer may be adjusted to satisfy 4 μm≦tc≦20 μm to shorten an internal current path, thereby allowing for a reduction in equivalent series inductance (ESL).

Other characteristics are the same as those of the PCB having a multilayer ceramic electronic component embedded therein according to the foregoing embodiment of the present invention, so description thereof will be omitted.

As set forth above, according to embodiments of the present invention, equivalent series inductance (ESL) may be reduced by shortening a current path by adjusting the thickness of the upper or lower cover layer and the thickness of the external electrode of the multilayer ceramic electronic component to be embedded in a board.

Also, according to embodiments of the present invention, bonding characteristics capable of improving delamination between the multilayer ceramic electronic component and the board by adjusting surface roughness of the plating layer, while low inductance may be implemented.

While the present invention has been shown and described in connection with the embodiments, it will be apparent to those skilled in the art that modifications and variations may be made without departing from the spirit and scope of the invention as defined by the appended claims.

What is claimed is:

1. A multilayer ceramic electronic component to be embedded in a board, comprising:
a ceramic body including dielectric layers and having first and second main surfaces facing each other, first and second side surfaces facing each other, and first and second end surfaces facing each other;
an active layer including a plurality of first and second internal electrodes alternately exposed through both end surfaces of the ceramic body with the dielectric layers interposed therebetween, to form capacitance therein;
upper and lower cover layers formed on upper and lower portions of the active layer; and
first and second external electrodes formed on both end surfaces of the ceramic body,
wherein the first external electrode includes a first base electrode and a first terminal electrode formed on the first base electrode, the second external electrode includes a second base electrode and a second terminal electrode formed on the second base electrode, and when a thickness of the upper or lower cover layer is defined as tc, 4 μm≦tc≦20 μm is satisfied,
and the first and second terminal electrodes are formed of copper (Cu) through plating, and when a thickness of the ceramic body is defined as ts, ts≦250 μm is satisfied.

2. The multilayer ceramic electronic component of claim 1, wherein when a thickness of the first and second terminal electrodes is defined as tp, tp≧5 μm is satisfied.

3. The multilayer ceramic electronic component of claim 1, wherein when surface roughness of the first and second terminal electrodes is defined as Ra and a thickness of the first and second terminal electrodes is defined as tp, 200 nm≦Ra≦tp is satisfied.

4. A printed circuit board having a multilayer ceramic electronic component embedded therein, the printed circuit board comprising:
an insulating substrate; and
the multilayer ceramic electronic component including, a ceramic body including dielectric layers and having first and second main surfaces facing each other, first and second side surfaces facing each other, and first and second end surfaces facing each other; an active layer including a plurality of first and second internal electrodes alternately exposed through both end surfaces of the ceramic body with the dielectric layers interposed therebetween, to form capacitance therein; upper and lower cover layers formed on upper and lower portions of the active layer; and first and second external electrodes formed on both end surfaces of the ceramic body, wherein the first external electrode includes a first base electrode and a first terminal electrode formed on the first base electrode, the second external electrode includes a second base electrode and a second terminal electrode formed on the second base electrode, and when a thickness of the upper or lower cover layer is defined as tc, 4 μm≦tc≦20 μm is satisfied,
and the first and second terminal electrodes are formed of copper (Cu) through plating, and
when a thickness of the ceramic body is defined as ts, ts≦250 μm is satisfied.

5. The printed circuit board of claim 4, wherein when a thickness of the first and second terminal electrodes is defined as tp, tp≧5 μm is satisfied.

6. The printed circuit board of claim 4, wherein when surface roughness of the first and second terminal electrodes is defined as Ra and a thickness of the first and second terminal electrodes is defined as tp, 200 nm≦Ra≦tp is satisfied.

7. The multilayer ceramic electronic component of claim 1, wherein when a thickness of a region of the first or second base electrode connected to the uppermost internal electrode among the first and second internal electrodes is defined as ta, 10 μm≦ta≦50 μm is satisfied.

8. The printed circuit board of claim 4, wherein when a thickness of a region of the first or second base electrode connected to the uppermost internal electrode among the first and second internal electrodes is defined as ta, 10 μm≦ta≦50 μm is satisfied.
